(19) United States
(12) Patent Application Publication
(10) Pub. No.: US 2004/0149898 A1
(43) Pub. Date: Aug. 5, 2004

(54) Injection-molded structure of an image sensor and method for manufacturing the same

(76) Inventors: Jackson Hsieh, Hsinchu Hsien (TW); Jichen Wu, Hsinchu Hsien (TW); Bruce Chen, Hsinchu Hsien (TW); Abnet Chen, Hsinchu Hsien (TW)

Correspondence Address: PRO-TECHTOR INTERNATIONAL, 20775 Norada Court, Saratoga, CA, 95070-3018, US

(21) Appl. No.: 10/356,756

(22) Filed: Jan. 30, 2003

(51) Int. Cl. H01J 5/02

(52) U.S. Cl. 250/239

(57) ABSTRACT

An injection-molded structure of an image sensor to be electrically connected to a printed circuit board. The image sensor includes metal sheets arranged in a matrix, a U-shaped injection molding structure encapsulating the metal sheets by way of injection molding, a photosensitive chip having a plurality of bonding pads, wires, and a transparent layer. Each metal sheet includes a first board. The injection molding structure has a first molded body, a second molded body, and a cavity. The first boards are exposed from the injection molding structure to form signal input and output terminals, respectively. The chip is arranged within the cavity. The wires electrically connect the bonding pads to the signal input terminals, respectively. The transparent layer is arranged on a top of the first molded body to cover over the chip. The invention also discloses a method for manufacturing the image sensor.

### BACKGROUND OF THE INVENTION

1. Field of the invention

The invention relates to an image sensor structure and a method for manufacturing the same, and in particular to an image sensor formed by way of injection molding.

2. Description of the Related Art

A general sensor is used for sensing signals, which may be optical or audio signals. The sensor of the invention is used for receiving image signals or optical signals. After receiving image signals, the image sensor converts the image signals into electrical signals, which are then transmitted to a printed circuit board via a substrate.

Referring to FIG. 1, a conventional method for packaging an image sensor includes the steps of:

providing a substrate 10 having an upper surface 11 formed with signal input terminals 18 and a lower surface 13 formed with signal output terminals 24;

providing a frame layer 12 on the substrate 10 to form a cavity 16 together with the substrate 10;

providing a photosensitive chip 14 on the substrate 10 and within the cavity 16, a plurality of bonding pads 20 being formed on the photosensitive chip 14;

providing a plurality of wires 15 for electrically connecting the bonding pads 20 of the photosensitive chip 14 to the signal input terminals 18 of the substrate 10, respectively; and

providing a transparent layer 22, which is coated with an adhesive layer 23, on the frame layer 12 for covering and encapsulating the photosensitive chip 14.

The image sensor manufactured according to the above-mentioned method has the following drawbacks.

1. The image sensor has to be individually manufactured and cannot be manufactured in mass production, so the cost thereof cannot be decreased.

2. During the packaging processes, a substrate 10 has to be provided for each package body, and then a frame layer 12 has to be adhered to the substrate 10. Therefore, the manufacturing processes are inconvenient and the material cost may be increased. In addition, the overflowing glue may influence the wire bonding process.

### SUMMARY OF THE INVENTION

An object of the invention is to provide an injection-molded structure of an image sensor and a method for manufacturing the same, wherein image sensors may be manufactured in mass production by way of injection molding so that the manufacturing cost may be reduced.

Another object of the invention is to provide an injection-molded structure of an image sensor and a method for manufacturing the same, wherein a frame layer of the image sensor is formed by way of injection molding so that overflowing glue, which may influence the wire bonding process, may be avoided.

Still another object of the invention is to provide an injection-molded structure of an image sensor and a method for manufacturing the same, wherein metal sheets are used instead of the substrate and traces thereon so that the material and manufacturing costs may be effectively reduced.

To achieve the above-mentioned objects, the invention provides an injection-molded structure of an image sensor to be electrically connected to a printed circuit board, the image sensor comprising: a plurality of metal sheets arranged in a matrix, each of the metal sheets including a first board; a U-shaped injection molding structure encapsulating the metal sheets by way of injection molding, wherein the injection molding structure has a first molded body, a second molded body, and a cavity, and the first boards of the metal sheets are exposed from the injection molding structure to form signal input terminals and signal output terminals, respectively; a photosensitive chip arranged within the cavity of the injection molding structure, the photosensitive chip having a plurality of bonding pads; a plurality of wires for electrically connecting the bonding pads of the photosensitive chip to the signal input terminals of the first boards of the metal sheets, respectively; and a transparent layer arranged on a top of the first molded body to cover over the photosensitive chip.

To achieve the above-mentioned objects, the invention also provides a method for manufacturing an image sensor. The method includes the steps of: providing a plurality of metal sheets arranged in a matrix, each of the metal sheets including a first board; encapsulating the metal sheets by an injection molding process to form an injection molding structure having a cavity, wherein the first boards of the metal sheets are exposed from the injection molding structure to form signal input terminals and signal output terminals; mounting a photosensitive chip, which has a plurality of bonding pads, within the cavity of the injection molding structure; providing a plurality of wires for electrically connecting the bonding pads of the photosensitive chip to the signal input terminals of the first boards of the metal sheets; and mounting a transparent layer to a top of the injection molding structure to cover over the photosensitive chip.

### BRIEF DESCRIPTION OF THE DRAWINGS

FIG. 1 is a schematic illustration showing a conventional image sensor.

FIG. 2 is a cross-sectional view showing an injection-molded structure of an image sensor of the invention.

FIG. 3 is a first schematic illustration showing the injection-molded structure of the image sensor of the invention.

FIG. 4 is a second schematic illustration showing the injection-molded structure of the image sensor of the invention.

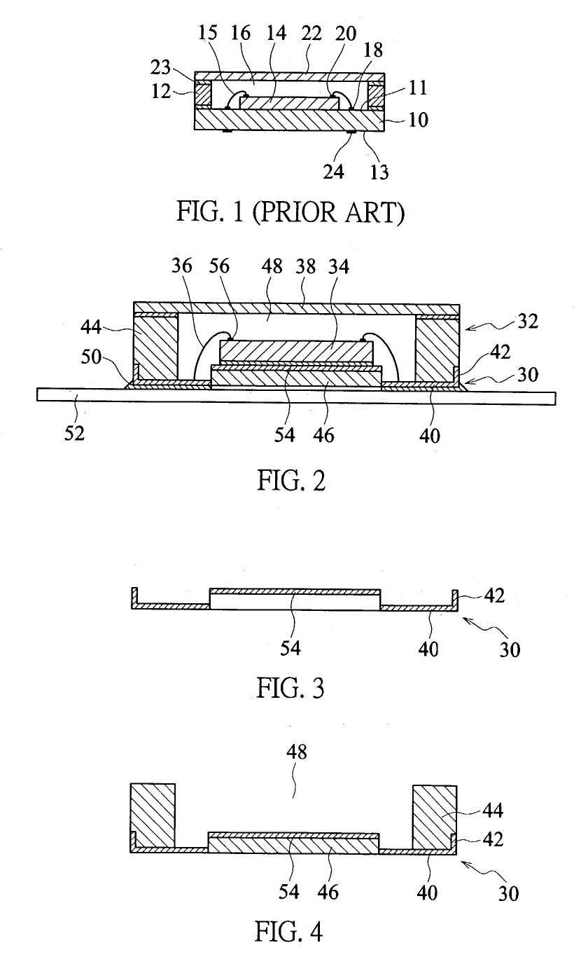

### DETAILED DESCRIPTION OF THE INVENTION

Referring to FIG. 2, an injection-molded structure of an image sensor according to an embodiment of the invention includes a plurality of metal sheets 30, an injection molding structure 32, a photosensitive chip 34, a plurality of wires 36, and a transparent layer 38.

Each metal sheet 30 includes a first board 40 and a second board 42 vertically connected to the first board 40 such that the metal sheet 30 has an L-shaped structure.

The injection molding structure 32 encapsulates the metal sheets 30 to form a first molded body 44 and a second molded body 46 and to form into a U-shape structure, which has a cavity 48, by way of injection molding. The first board 40 of each metal sheet 30 is exposed from the injection molding structure 32 and located within the cavity 48 to form a signal input terminal. In addition, each first board 40 is also exposed from a bottom surface of the injection molding structure 32 to form a signal output terminal. The first boards 40 are electrically connected to a printed circuit board 52 by solder tin 50 and a surface mounting technology (SMT). The second boards 42 are exposed from a side of the first molded body 44 so that the solder tin 50 may climb to the second boards 42 during the SMT process. Thus, the connection between the solder tin and the metal sheets are more firmly. In addition, a middle board 54 is arranged on the second molded body 46.

The photosensitive chip 34 having a plurality of bonding pads 56 is located within the cavity 48 of the injection molding structure 32 and above the middle board 54.

The wires 36 electrically connect the bonding pads 56 of the photosensitive chip 34 to the signal input terminals of the first boards 40 of the metal sheets 30, respectively.

The transparent layer 38 is arranged on a top of the first molded body 44 to cover over the photosensitive chip 34.

The method for manufacturing the image sensor of the invention will be described with reference to FIGS. 3 and 4.

First, a middle board 54 and a plurality of metal sheets 30, which surrounds the middle board 54 and is arranged in a matrix, are provided. Each metal sheet 30 includes a first board 40 and a second board 42 and is formed into an L-shaped structure. The first boards 40, second boards 42, and middle board 54 define a U-shaped structure, as shown in FIG. 3.

As shown in FIG. 4, the metal sheets 30 and the middle board 54 are integrally injection molded to form an injection molding structure 32 by way of injection molding. The injection molding structure 32 has a first molded body 44, a second molded body 46 and a cavity 48. The middle board 54 is positioned above the second molded body 46. The upper surfaces of the first boards 40 of the metal sheets 30 are positioned within the cavity 48 to form signal input terminals, while the lower surfaces of the first boards 40 are positioned on a bottom surface of the first molded body 44 to form signal output terminals. In addition, the second boards 42 are exposed from a side of the first molded body 44.

Please refer to FIGS. 4 and 2. Then, the photosensitive chip 34 is arranged on the middle board 54 positioned on a top of the second molded body 46. Next, a plurality of wires 36 is provided to electrically connect the bonding pads 56 of the photosensitive chip 34 to the signal input terminals of the first boards 40. Finally, the transparent layer 38 is arranged on the top of the first molded body 44 to cover over the photosensitive chip 34, and the package of the image sensor is thus completed.

When the image sensor is surface mounted to the printed circuit board 52, the solder tin 50 climbs to the second boards 42 from the first boards 40 so that the image sensor may be fixed to the printed circuit board 52 more firmly.

The image sensor of the invention and method for manufacturing the same have the following advantages.

1. Since each metal sheet 30 includes a first board 40 and a second board 42 connected to the first board 40 and the second board 42 is formed at a side of the first molded body 44, the solder tin 50 may climb to the second board 42 when the image sensor is surface mounted to the printed circuit board 52 so that the image sensor may be firmly fixed to the printed circuit board 52.

2. Because the image sensor is formed by way of injection molding, the manufacturing cost may be effectively reduced in a mass production process.

3. Since the frame layer is formed by way of injection molding, the overflowing glue may be avoided.

4. Since the metal sheets 30 are used instead of the conventional substrate and traces thereon, the material and manufacturing costs may be effectively reduced.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. An injection-molded structure of an image sensor to be electrically connected to a printed circuit board, the image sensor comprising:
a plurality of metal sheets arranged in a matrix, each of the metal sheets including a first board;
a U-shaped injection molding structure encapsulating the metal sheets by way of injection molding, wherein the injection molding structure has a first molded body, a second molded body, and a cavity, and the first boards of the metal sheets are exposed from the injection molding structure to form signal input terminals and signal output terminals, respectively;
a photosensitive chip arranged within the cavity of the injection molding structure, the photosensitive chip having a plurality of bonding pads;
a plurality of wires for electrically connecting the bonding pads of the photosensitive chip to the signal input terminals of the first boards of the metal sheets, respectively; and
a transparent layer arranged on a top of the first molded body to cover over the photosensitive chip.

2. The injection-molded structure of the image sensor according to claim 1, wherein each of the metal sheets further includes a second board, which is vertically connected to the first board and exposed from a side of the first molded body.

3. The injection-molded structure of the image sensor according to claim 1, further comprising a middle board arranged on the second molded body and exposed to the cavity, and the photosensitive chip is arranged on the middle board.

4. The injection-molded structure of the image sensor according to claim 1, wherein the signal output terminals of the first boards of the metal sheets are electrically connected to the printed circuit board by solder tin.

5. The injection-molded structure of the image sensor according to claim 2, wherein the signal output terminals of the first boards of the metal sheets are electrically connected to the printed circuit board by solder tin, and the solder tin climbs to the second boards of the metal sheets.

6. A method for manufacturing an injection-molded structure of an image sensor, comprising the steps of:
providing a plurality of metal sheets arranged in a matrix, each of the metal sheets including a first board;
encapsulating the metal sheets by an injection molding process to form an injection molding structure having a cavity, wherein the first boards of the metal sheets are exposed from the injection molding structure to form signal input terminals and signal output terminals;
mounting a photosensitive chip, which has a plurality of bonding pads, within the cavity of the injection molding structure;
providing a plurality of wires for electrically connecting the bonding pads of the photosensitive chip to the signal input terminals of the first boards of the metal sheets; and
mounting a transparent layer to a top of the injection molding structure to cover over the photosensitive chip.

7. The method according to claim 6, wherein each of the metal sheets further includes a second board, which is vertically connected to the first board and exposed from a side of the injection molding structure.

8. The method according to claim 6, wherein the photosensitive chip is mounted to a middle board arranged on the second molded body.
